(19) United States
(12) Patent Application Publication
(10) Pub. No.: US 2014/0090700 A1
(43) Pub. Date: Apr. 3, 2014

(54) HIGH-CONCENTRATION MULTI-JUNCTION SOLAR CELL AND METHOD FOR FABRICATING SAME

(71) Applicants: Minghui Song, Xiamen (CN); Guijiang Lin, Xiamen (CN); Zhihao Wu, Xiamen (CN); Liangjun Wang, Xiamen (CN); Jianqing Liu, Xiamen (CN); Jingfeng Bi, Xiamen (CN); Weiping Xiong, Xiamen (CN); Zhidong Lin, Xiamen (CN)

(72) Inventors: Minghui Song, Xiamen (CN); Guijiang Lin, Xiamen (CN); Zhihao Wu, Xiamen (CN); Liangjun Wang, Xiamen (CN); Jianqing Liu, Xiamen (CN); Jingfeng Bi, Xiamen (CN); Weiping Xiong, Xiamen (CN); Zhidong Lin, Xiamen (CN)

(73) Assignee: Xiamen Sanan Optoelectroics Technology Co., Ltd., Xiamen City, Fujian Province (CN)

(21) Appl. No.: 14/124,579

(22) PCT Filed: May 7, 2012
(86) PCT No.: PCT/CN2012/075134

§ 371 Date: Dec. 6, 2013

(30) Foreign Application Priority Data
Jun. 22, 2011 (CN) 201110168522.9

(51) Int. Cl. H01L 31/0687; H01L 31/0725

(52) U.S. Cl. CPC H01L 31/0687; H01L 31/0725
USPC 136/255; 438/74

(57) ABSTRACT

A high-concentration multi-junction solar cell and method for fabricating same is provided. The high-concentration multi-junction solar cell comprises a top cell, an intermediate cell, a bottom cell and two tunneling junctions connecting the top cell and intermediate cell and the intermediate cell and bottom cell. The emitter layers of the top and intermediate cells both employ the graded doping concentrations and have high open circuit voltage and short circuit current. The top cell emitter layer is over several hundred nanometers thicker than that of the traditional multi-junction cell so as to decrease the whole series resistance of the multi-junction cell, improve the fill factor, and gain higher photoelectric conversion efficiency.

### CROSS-REFERENCE TO RELATED APPLICATIONS

This application claims priority to PCT/CN2012/075134 filed on May 7, 2012 and published on Dec. 27, 2012 as publication WO 2012/174952, which claims priority to Chinese Patent Application No. 201110168522.9 entitled “High-concentration multi-junction solar cell and method for fabricating same”, filed on Jun. 22, 2011, the contents of which are incorporated herein by reference in its entirety.

### FIELD OF THE INVENTION

This invention pertains to the field of compound semiconductor solar cell, and specifically relates to a high-concentration multi-junction solar cell and a method for fabricating the same.

### BACKGROUND OF THE INVENTION

The photovoltaic power generation technology, after the development of the first-generation crystalline silicon cells and the second-generation thin film photovoltaic cells, is now entering upon an age of the second-generation concentrated photovoltaic (CPV) technology. III-V concentrating multi-junction solar cell serves as the core of CPV technology. Compared with other types of solar cells, III-V concentrating multi-junction solar cell features high photoelectric conversion efficiency, excellent temperature characteristics, short energy recovery period and the like. It allows maximized use of solar energy resources and reduces harm to the environment due to construction of power plants.

The multi-junction solar cell is made by the connection through tunneling junction of several semiconductor cells with different band gaps. Different sub-cells absorb the solar spectrum of different wavelengths and further convert the solar energy as much as possible into the electric energy. With the unique design idea and high photoelectric conversion efficiency, the multi-junction solar cell has become the basic cell structure employed presently for the research of solar cell by research institutes and enterprises of the photovoltaic field around the world. Spire Corporation declared in October 2010 that it had developed a triple junction solar cell. With an area of 0.97 cm² under the test conditions of 406 times of concentration of solar radiation, AM1.5 atmospheric optical quality and the temperature of 25° C., the triple junction solar cell has the conversion efficiency of up to 42.3%. The InGaP/(In)GaAs/Ge triple junction solar cell manufactured by Emcore, a major player of CPV in the world, has the conversion efficiency of 39% under 500 times of solar concentration and of 36.3% under 1150 times of solar concentration. Along with the advancing CPV technology industrialization, high-concentration (−1000×) solar cells have become the key product in the CPV industry due to its outstanding cost effectiveness. This kind of cell can concentrate, through a condensing lens, solar energy hundreds of thousands of times on a very small cell chip for power generation so as to greatly reduce the number of solar cell chip needed. Along with the comparatively high open circuit voltage and short-circuit current under high concentration (−1000×), the cell can also produce greater series resistance, which seriously affects the fill factor of cell and decreases the conversion efficiency.

### SUMMARY

The object of this invention is to provide a novel high-concentration multi-junction solar cell, which not only has high open circuit voltage and short circuit current, but also keeps high fill factor, i.e., to keep high photoelectric conversion efficiency under high concentration condition.

In accordance with an aspect of the invention, a high-concentration multi-junction solar cell is provided, comprising: a top cell, an intermediate cell, a bottom cell, and two tunneling junctions. The emitter layers of the top cell and the intermediate cell both feature graded doping concentrations, and the top cell emitter layer is over 100 nm thicker than that of the traditional multi-junction cell.

As is well known in the art of solar cells, an emitter layer forms a p-n junction with an underlying layer, typically having the same conductivity type as the substrate. Emitter layers are typically n-type and the substrate is a p-type. By a built-in potential difference generated due to the p-n junction, a plurality of electron-hole pairs, which are generated by incident light into the emitter layer, are separated into electrons and holes, and the separated electrons move toward the n-type semiconductor and the separated holes move toward the p-type semiconductor. Thus, when the substrate is of the p-type and the emitter layer is of the n-type, the separated holes move toward the substrate and the separated electrons move toward the emitter layer. Accordingly, the holes become major carriers in the substrate and the electrons become major carriers in the emitter layer. By providing a plurality of stacked p-n junctions (i.e., multiple emitter layers), there is more of a likelihood that a photon from the sunlight entering the solar cell will create an electron-hole pair near a pn junction, to effectively convert the photon to current.

Preferably, the top cell emitter layer has a thickness of 0.05-0.5 microns.

Preferably, the top cell emitter layer has a thickness of 0.3 microns.

Preferably, in the top cell and intermediate cell, the emitter layer close to the base area is a low doping concentration area, with a doping concentration of 1×10¹⁷/cm³-1×10¹⁸/cm³ and the emitter layer far from the base area is a high doping concentration, with a doping concentration of 1×10¹⁸/cm³-1×10¹⁹/cm³.

Preferably, the doping concentration of the top cell emitter layer is graded from 5×10¹⁷/cm³ to 5×10¹⁸/cm³.

Preferably, the doping concentration of the intermediate cell emitter layer is graded from 5×10¹⁷/cm³ to 5×10¹⁸/cm³.

In accordance with an aspect of the invention, a method for fabricating the high-concentration multi-junction solar cell is provided, comprising the following steps: by the epitaxial method including metal organic chemical vapor deposition (MOCVD), molecular beam epitaxy (MBE) or ultrahigh vacuum chemical vapor deposition (UHVCVD), a Ge bottom cell grows epitaxially on a selected Ge substrate; a GaAs tunneling junction grows epitaxially on the Ge substrate; a base area of a (In) GaAs intermediate cell grows epitaxially on the GaAs tunneling junction; an (In) GaAs intermediate cell emitter layer grows epitaxially on the base area of the (In) GaAs intermediate cell, forming the (In) GaAs intermediate cell; an AlGaAs tunneling junction grows epitaxially on the (In) GaAs intermediate cell; an InGaP top cell base area grows epitaxially on the AlGaAs tunneling junction; a thick and graded doping InGaP top cell emitter layer grows epitaxially on the InGaP top cell base area, forming the InGaP top cell.

Preferably, the doping concentration of the intermediate cell emitter layer is graded, including step grading and continuous grading; the emitter layer close to the base area is a low doping concentration area, with a doping concentration of 1×10¹⁷/cm³-1×10¹⁸/cm³, and that far from the base area is a high doping concentration area, with a doping concentration of 1×10¹⁸/cm³-1×10¹⁹/cm³.

Preferably, the doping concentration of the top cell emitter layer is graded, including step grading and continuous grading; the emitter layer close to the base area is a low doping concentration area, with a doping concentration of 1×10¹⁷/cm³-1×10¹⁸/cm³, and that far from the base area is a high doping concentration area, with a doping concentration of 1×10¹⁸/cm³-1×10¹⁹/cm³.

Preferably, the doping concentration of the said top cell and intermediate cell emitter layers is graded from 5×10¹⁷/cm³ to 5×10¹⁸/cm³.

Preferably, the thickness of the whole top cell emitter layer is 0.05-0.5 micron.

Each sub-cell emitter layer of the traditional multi-junction solar cell is uniformly doped, and the thinner the emitter layer is, the higher the photoelectric conversion efficiency of the cell is. However, under the high-concentration condition, the thinner top cell emitter layer produces greater series resistance, which decreases the fill factor of the cell and finally affects the conversion efficiency. The invention relates to a high-concentration multi-junction solar cell. The emitter layers of the top and intermediate cells both employ the graded doping concentration and have high open circuit voltage and short circuit current; meanwhile, under the high concentration condition, the top cell emitter layer is allowed to have greater thickness compared with the traditional multi-junction cell so as to decrease the total series resistance of the multi-junction cell, improve the fill factor and finally gain higher photoelectric conversion efficiency.

### BRIEF DESCRIPTION OF THE DRAWINGS

The attached drawings help further understand this invention and constitute a part of the instructions. Together with the embodiments of the invention, these drawings are used for explaining the invention, but do not constitute a limitation to the invention. In addition, figures on the attached drawings are just to describe an outline of the invention rather than being drawn in proportion.

FIG. 1 is the cross sectional view of a high-concentration multi-junction solar cell of the invention.

In the figure,
100: p-type Ge substrate;
101: n-type Ga_{0.5}In_{0.5}P window layer
200: GaAs tunneling junction;
300: (In)GaAs intermediate cell back surface field layer;
301: (In) GaAs intermediate cell base area;
302: (In) GaAs intermediate cell emitter layer;
303: (In) GaAs intermediate cell window layer;
400: AlGaAs tunneling junction;
500: GaInP top cell back surface field layer;
501: GaInP top cell base area;
502: GaInP top cell emitter layer;
503: GaInP top cell window layer
A: Ge bottom cell;
B: intermediate cell;
C: top cell.

### DETAILED DESCRIPTION

Detailed explanation will be given to the invention by combining the attached drawings and the embodiments. It should be noted that in case of no discrepancies, the embodiments of the invention and each feature of the embodiment can be combined with each other and those are all within the protection scope of the invention.

### Embodiment One

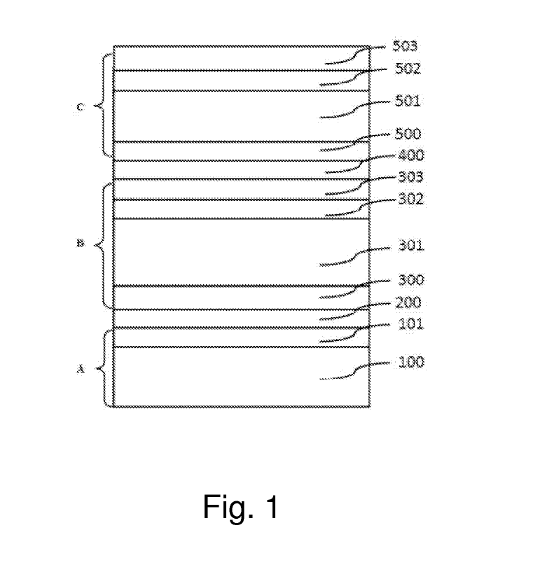

As illustrated in FIG. 1, a high-concentration multi-junction solar cell comprises a Ge bottom cell A, an intermediate cell B, a top cell C and two tunneling junctions 200 and 400 connecting the cells.

More specifically, the figure shows: one P-type Ge substrate 100 and one n-type Ga_{0.5}In_{0.5}P window layer 101 deposited on the substrate, which form a Ge bottom cell A.

A series of highly doped P-type and n-type layers are deposited on the top of the Ge bottom cell A, forming a GaAs tunneling junction 200 and used for connecting the Ge bottom cell A to the intermediate cell B.

An intermediate cell back surface field layer 300 is deposited on the top of the formed GaAs tunneling junction 200 and used for reducing recombination loss. The layer is preferably formed by P-type AlGaAs.

An intermediate cell base area 301 and an intermediate cell emitter layer 302 are deposited on an intermediate cell back surface field layer 300. In the preferred embodiment, the intermediate cell base area 301 is formed by P-type (In) GaAs with a thickness of 3.5 micron; the intermediate cell emitter layer 302 is formed by n-type (In) GaAs with a thickness of 0.1 micron, and the n-type doping is gradually increased with the thickness and the doping concentration is continuously graded from 5×10¹⁷/cm³ to 5×10¹⁸/cm³. An intermediate cell window layer 303 formed by n-type AlInP is deposited on the intermediate cell emitter layer 302, forming the intermediate cell B.

A tunneling junction 400 preferably formed by AlGaAs is deposited on the top of the intermediate cell B and used for connecting the intermediate cell B to the top cell C.

A top cell back surface field layer 500 preferably formed by P-type AlInGaP is deposited on the top of the tunneling junction 400.

A top cell base area 501 and a top cell emitter layer 502 are deposited on the top of the top cell back surface field layer 500. In the preferred embodiment, the top cell base area 501 is formed by a 0.8 micron thick P-type GaInP; the top cell emitter layer 502 is formed by 0.3 micron thick n-type GaInP, and the doping concentration is continuously graded from 5×10¹⁷/cm³ to 5×10¹⁸/cm³ as the n-type doping is gradually increased with the thickness. A top cell window layer 503 formed by n-type AlInP is deposited on the top cell emitter layer 502, forming the top cell C. Therefore, the emitter layers of the top cell and the intermediate cell both contain a graded doping concentration, and the thickness of the top cell emitter layer is 0.3-0.5 micron to decrease the total series resistance of the multi-junction solar cell.

### Embodiment Two

The embodiment is a fabricating process of the high-concentration multi-junction solar cell in Embodiment One, comprising the process of the sub-cells A, B and C and each layer between the sub-cells. In the course of MOCVD epitaxial growth, by controlling and adjusting the flow ratio of n-type dopant source in the reaction source, the grading of the doping concentration of the emitter layer can be realized.

The specific fabrication process comprises the following steps:

The p-type doped Ge substrate 100 has a thickness of 150 micron and functions as the Ge bottom cell base area.

The P-type Ge substrate 100 is well cleaned and placed in a MOCVD reaction chamber; first the P-type Ge substrate 100 is baked for ten minutes at the temperature of 750° C. and then decreased to a temperature of 600° C. n-type Ga_{0.5}In_{0.5}P window layer 101 grows epitaxially to form the Ge bottom cell A.

The GaAs tunneling junction 200 connecting the bottom and intermediate cells grows epitaxially on the Ge bottom cell.

The back surface field layer 300 of the intermediate cell B grows to prevent the photo-generated electron of the intermediate cell base area from spreading to the bottom cell. The specific method is as follows: the temperature of the MOCVD reaction chamber is controlled to be 620° C. and V/III source molar flow ratio to be 120; and a layer of P-type Al_{0.2}Ga_{0.8}As grows epitaxially on the GaAs tunneling junction 200 and functions as the back surface field layer of the intermediate cell B.

The base area 301 and emitter layer 302 of the intermediate cell B grow epitaxially on the back surface field layer of the intermediate cell B. After the V/III source molar flow ratio in the MOCVD reaction chamber is regulated to be 40, a layer of P-type In_{0.01}Ga_{0.99}As grows epitaxially on the back surface field layer 300 of the intermediate cell B and functions as the base area 301 of the intermediate cell B, with a thickness of 3.5 micron. And the emitter layer 302 grows epitaxially on the intermediate cell base area 301. In the course of MOCVD epitaxial growth, a low n-type dopant flow is used in the initial stage of the growth and the dopant flow is increased with the thickness of the emitter layer and finally the doping concentration is continuously graded from 5×10¹⁷/cm³ to 5×10¹⁸/cm³, namely the n-type In_{0.01}Ga_{0.99}As intermediate cell emitter layer 302, with a thickness of 0.1 micron.

A layer of n-type AlInP grows epitaxially on the emitter layer 302 of the intermediate cell B and functions as the window layer 303 of the intermediate cell B, forming the In_{0.01}Ga_{0.99}As intermediate cell B.

The AlGaAs tunneling junction 400 grows epitaxially on the In_{0.01}Ga_{0.99}As intermediate cell B.

The back surface field layer 500 of the top cell C grows to prevent the photo-generated electron of the top cell base area from spreading to the intermediate cell. The specific method is as follows: the temperature of the MOCVD reaction chamber is controlled to be 650° C. and the V/III source molar flow ratio to be 200; and a layer of p-type AlInGaP grows epitaxially on the AlGaAs tunneling junction 400 and functions as the back surface field layer 500 of the top cell C.

The base area 501 and emitter layer 502 forming the top cell C grow epitaxially on the back surface field layer 500 of the top cell C. After the V/III source molar flow ratio is regulated to be 180, a layer of P-type Ga_{0.5}In_{0.5}P grows epitaxially on the back surface field layer 500 of the top cell B and functions as the base area 501 of the top cell B, with a thickness of 0.8 micron. And the top cell emitter layer 502 grows epitaxially on the top cell base area 501. In the course of MOCVD epitaxial growth, a low n-type dopant flow is used in the initial stage of the growth and the dopant flow is increased with the thickness of the emitter layer and finally the doping concentration is continuously graded from 5×10¹⁷/cm³ to 5×10¹⁸/cm³, namely the n-type Ga_{0.5}In_{0.5}P top cell emitter layer 502, with a thickness of 0.3 micron.

A layer of n-type AlInP grows epitaxially on the emitter layer 502 of the top cell B and functions as the window layer 503 of the top cell B, forming the Ga_{0.5}In_{0.5}P top cell C.

While particular embodiments of the present invention have been shown and described, it will be obvious to those skilled in the art that changes and modifications may be made without departing from this invention in its broader aspects and, therefore, the appended claims are to encompass within their scope all such changes and modifications that are within the true spirit and scope of this invention.

What is claimed is:

1. A multi-junction solar cell comprising:
a top cell having an emitter layer;
an intermediate cell having an emitter layer;
a bottom cell; and
a first tunneling junction connecting the top cell and intermediate cell; and
a second tunneling junction connecting the intermediate cell and bottom cell,
wherein the emitter layers of the top cell and the intermediate cell both contain a graded doping concentration and a thickness of the top cell emitter layer is 0.3-0.5 micron.

2. The multi-junction solar cell according to claim 1, wherein a thickness of the top cell emitter layer is 0.3 micron.

3. The multi-junction solar cell according to claim 1, wherein a doping of the emitter layer of the top cell increases with the thickness of the top cell emitter layer, and a doping of the emitter layer of the intermediate cell increases with the thickness of the intermediate cell layer.

4. The multi-junction solar cell according to claim 3, wherein the doping concentration of the emitter layer of the top cell is graded from 5×10¹⁷/cm³ to 5×10¹⁸/cm³.

5. The multi-junction solar cell according to claim 3, wherein the doping concentration of the emitter layer of the intermediate cell is graded from 5×10¹⁷/cm³ to 5×10¹⁸/cm³.

6. A method for fabricating a multi-junction solar cell comprising:
fabricating a bottom cell;
epitaxially growing a first tunneling junction on the said bottom cell;
forming an intermediate cell on said first tunneling junction, the intermediate cell having an emitter layer, wherein the emitter layer of the intermediate cell is grown to have a graded doping concentration;
epitaxially growing a second tunneling junction on said intermediate cell; and
forming a top cell on said second tunneling junction, the top cell having an emitter layer, wherein the emitter layer of the top cell is grown to have a graded doping concentration.

7. The method according to claim 6, wherein the intermediate cell is fabricated on said first tunneling junction, and said intermediate cell has the graded doping concentration of its emitter layer formed by the method comprising:
epitaxially growing a back surface field layer of the intermediate cell on said first tunneling junction;
epitaxially growing a base area of said intermediate cell on the back surface field layer of the intermediate cell;
epitaxially growing the emitter layer of said intermediate cell, with the graded doping concentration, on the base area of the intermediate cell; and
epitaxially growing a window layer of the said intermediate cell on the emitter layer of the intermediate cell.

8. The method according to claim 7, wherein the dopant concentration in the emitter layer of the intermediate cell increases with the thickness of the emitter layer.

9. The method according to claim 6, wherein the top cell is fabricated on said second tunneling junction, and said top cell has an emitter layer, with the graded doping concentration, formed using a method comprising:
epitaxially growing a back surface field layer of the top cell on said second tunneling junction;
epitaxially growing a base area of the said top cell on the back surface field layer of the top cell;
epitaxially growing the emitter layer of said top cell, having the graded doping concentration, on the base area of the top cell; and
epitaxially growing a window layer of the said top cell on the emitter layer of the top cell.

10. The method according to claim 9, wherein the dopant concentration in the emitter layer of the top cell increases with the thickness of the emitter layer.

11. The method according to claim 9, wherein the emitter layer of the top cell has a thickness of 0.3 micron, and is epitaxially grown on the base area of the top cell.

12. The method according to claim 9, wherein the emitter layer of the top cell has a thickness of 0.05-0.5 micron, and is epitaxially grown on the base area of the top cell.

13. The method according to claim 6, wherein the method of fabricating the bottom cell comprises:
providing a Ge substrate; and
epitaxially growing a window layer of the bottom cell on said Ge substrate.

14. The method according to claim 6, wherein the doping concentration of the emitter layers of the top cell and the intermediate cell is graded respectively from 5×10¹⁷/cm³ to 5×10¹⁸/cm³.

15. The method according to claim 6, wherein in the emitter layer of the intermediate cell and the emitter layer of the top cell are epitaxially grown by an MOCVD method, wherein a gas flow ratio of a dopant source in an MOCVD reactor is varied while the emitter layers of the intermediate cell and top cell are grown.
